(19) United States
(12) Patent Application Publication
(10) Pub. No.: US 2024/0173578 A1
(43) Pub. Date: May 30, 2024

(54) DECT System With Two or More Diverse Antennas for a Respiratory Protection Mask

(71) Applicants: 3M INNOVATIVE PROPERTIES COMPANY, St. Paul, MN (US); RTX A/S Company, Nørresundby (DK)

(72) Inventors: Darin K. Thompson, Huntersville, NC (US); Graham Wilson, Flint (GB); Gareth D. Evans, Wrexham (GB); Klaus A. Pedersen, Aalborg (DK)

(21) Appl. No.: 18/281,250

(22) PCT Filed: Mar. 8, 2022
(86) PCT No.: PCT/IB2022/052067

§ 371 Date: Sep. 8, 2023

Related U.S. Application Data
(60) Provisional application No. 63/161,042, filed on Mar. 15, 2021.

(51) Int. Cl. A62B 18/08; H01Q 1/27; H01R 13/52; H04B 7/04; H05K 1/14

(52) U.S. Cl. CPC A62B 18/08; H01Q 1/273; H01R 13/5224; H04B 7/04; H05K 1/148; H05K 2201/10189

(57) ABSTRACT

An apparatus for digital enhanced cordless telecommunications (DECT) on a respiratory protection mask having two or more diverse antennas is disclosed. According to one aspect, a communication module in a respiratory protection mask is configured to send and receive radio signals. The communication module includes a first antenna within the communication module and a second antenna within the communication module, the second antenna being separated from the first antenna to achieve antenna spatial diversity.

### TECHNICAL FIELD

This disclosure relates to a method and system for digital enhanced cordless telecommunications (DECT) on a respiratory protection mask having two or more diverse antennas.

### BACKGROUND

Respiratory protection masks are used by first responders and others to breathe clean air when in an environment with unclean air. For example, a respiratory protection mask (RPM) may be worn by a firefighter in a burning structure, or by a chemical hazards worker cleaning a hazardous chemical leak or spill. In addition to enabling the wearer of the RPM to breathe clean air, the RPM may also be equipped with a radio and antenna to enable the wearer to communicate with others over the air by radio. A problem with RPM radios is sensitivity to multipath fading. Multipath fading is the result of the radio signals reflecting off building walls, for example, and arriving at the RPM radio antenna from different directions along different paths of different lengths. As a consequence of multipath fading, the RPM wearer will hear the radio signal significantly fade in volume as he or she moves from one position to another.

### SUMMARY

Some embodiments advantageously provide a method and system for digital enhanced cordless telecommunications (DECT) on a RPM having two or more diverse antennas. According to one aspect, an audio communication module is equipped with at least two antennas that are spatially separated to achieve antenna spatial diversity. Antenna spatial diversity overcomes multipath fading by spacing the antennas far enough apart that the signals arriving at each antenna are substantially uncorrelated, and are therefore unlikely to fade at the same time. Antenna spatial diversity allows the wearer of the RPM to move in buildings, for example, without experiencing significant fading of the communication signal received by the wearer. The antennas are designed to fit in an existing form factor of an audio communications module such as 3M's CREW TALK, while having enough separation between the antennas to achieve antenna spatial diversity. In some embodiments, two printed circuit boards (PCBs), each having an antenna, are separated, one PCB being located in a lower portion of the audio communication module and another PCB being located in an upper portion of the audio communication module. In some embodiments, the two PCBs are connected by a short length of flexible cable to transfer the signal from the lower antenna to the upper PCB. In some embodiments, the electronics for processing the signals from both antennas are in the upper portion of the audio communication module, where there is more room. In some embodiments, at least one of the plurality of antennas in the audio communication module is formed by metal-plating an edge of a PCB.

### BRIEF DESCRIPTION OF THE DRAWINGS

A more complete understanding of embodiments described herein, and the attendant advantages and features thereof, will be more readily understood by reference to the following detailed description when considered in conjunction with the accompanying drawings wherein:

FIG. 1 shows a partially unassembled RPM along with several optional devices that may be attached to the RPM;

FIG. 2A shows a front view of an audio communication module constructed according to principles disclosed herein;

FIG. 2B shows a rear view of the audio communication module of FIG. 2A;

FIG. 3 shows the audio communication module assembled and attached to the RPM;

FIG. 4 shows an exploded view of an embodiment of the audio communication module;

FIG. 5 shows another view of the embodiment of the audio communication module of FIG. 4;

FIG. 6 shows a view of the outer housing in two parts;

FIG. 7A is a perspective view of a universal expansion port (UEP) interface and spacer;

FIG. 7B is a perspective view of the UEP block, potting cap and rib;

FIG. 8 is an illustration of two PCBs at least one of which has a plated edge antenna, and both of which have copper keep out regions;

FIG. 9 is an illustration of two PCBs, one of which has a copper keep out region;

FIG. 10 is an illustration of an upper PCB having a plated edge antenna; and

FIG. 11 is an illustration of a lower PCB and lower antenna.

### DETAILED DESCRIPTION

Before describing in detail exemplary embodiments, it is noted that the embodiments reside primarily in combinations of apparatus components and processing steps related to digital enhanced cordless telecommunications (DECT) on a RPM having two or more diverse antennas. Accordingly, the system and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate and modifications and variations are possible of achieving the electrical and data communication.

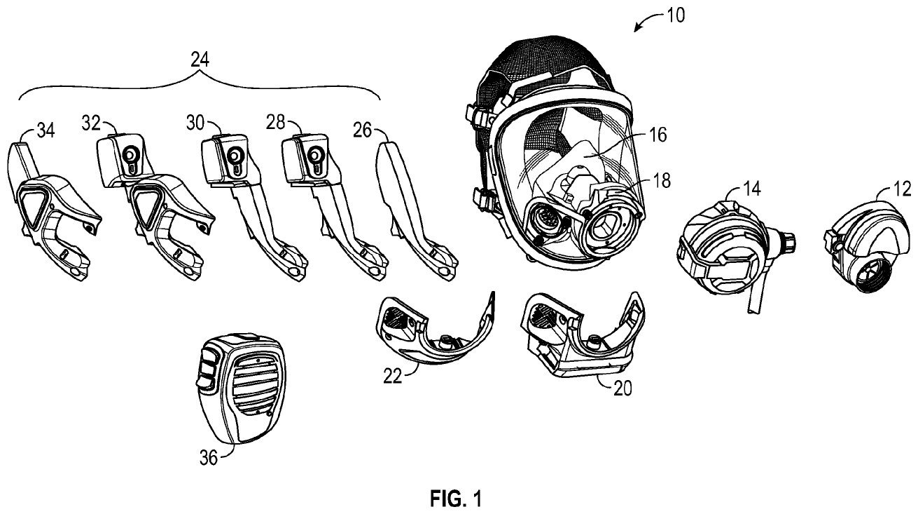

Referring now to the drawing figures, FIG. 1 shows a partially unassembled RPM 10 along with several optional devices that may be removably attached to the RPM 10. The RPM 10 may include: an air purifying respirator (APR) adapter 12 to purify the air and an air regulator 14 which regulates the air breathed in by the wearer of the RPM 10 and may permit exhaust of the air exhaled by the wearer. The RPM 10 also includes an in-mask display unit (IMD) 16 to display information to the wearer of the RPM 10 and a mask communication unit (MCU) 18 which receives voice waves from the wearer and converts the voice waves to an electrical signal to be processed and transmitted over the air via an antenna. The RPM 10 may also include the following components: communications module 20 with a battery and/or a basic module 22. The RPM 10 may include a communications assembly 24. The communications assembly 24 may include any one or more of: a bone transducer headphone control module 26; bone transducer control module 28; in-mask sight (display) module 30 such as a SCOTT SIGHT module; bone transducer 32; and an audio communication module 34. Optionally, a wireless voice amplifier (WVA) 36 is included to amplify the voice of the wearer. This disclosure is directed to the audio communication module 34.

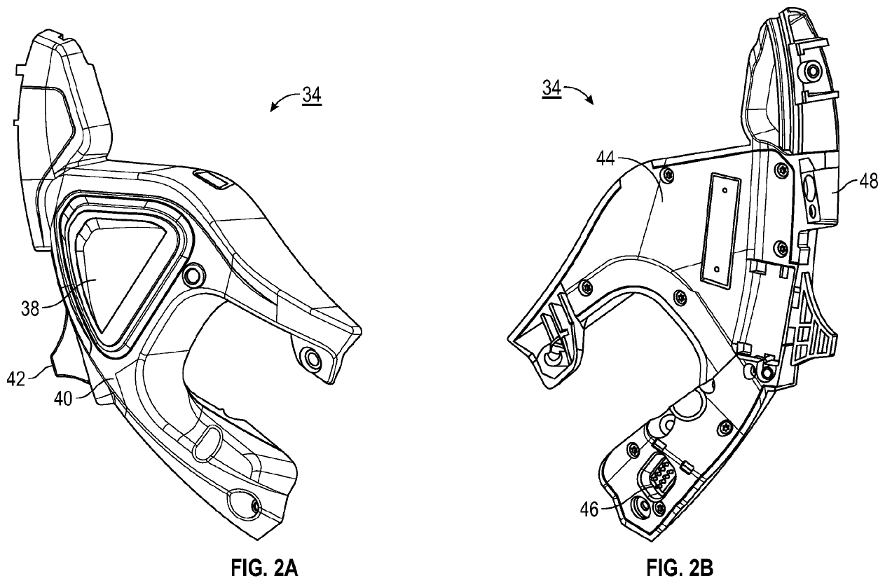

FIGS. 2A and 2B show a front view (FIG. 2A) and a rear view (FIG. 2B) of an example audio communication module 34 constructed in accordance with the principles of the present disclosure. Referring to FIG. 2A, the audio communication module 34 includes a push to talk (PTT) button 38 accessibly housed in the outer housing 40 of the audio communication module 34. A volume slider 42 enables the wearer to increase or decrease the volume of sound communicated to the wearer by sliding the volume slider 42. Referring to FIG. 2B, the audio communication module 34 has a lid 44 that encloses communication electronics housed by the audio communication module 34. The communication electronics may include a transceiver and an antenna for communicating with a remote transceiver such as the remote transceiver at a central location and/or a remote transceiver at the RPM 10 of another first responder. The audio communication module 34 may also have one or more electrical connectors such as UEP connector 46 and BCH connector 48.

The audio communication module 34 has a lower portion (having the lower antenna and UEP connector 46) that is curved and relatively narrow compared to the broad upper portion (having the PTT button 38, an upper antenna, and radio signal processing electronics). One purpose of curvature of the audio communication module 34 is to conform the audio communication module 34 to the curvature of the side of the RFP 10 from the ear down to near the mouth. The lower portion of the audio communication module 34 curves toward a front of the RPM 10 where the MCU 18 is located and the upper portion of the audio communication module 34 is located at a side of the RPM 10 where the cheek and ear of a wearer would be when the RPM 10 is worn.

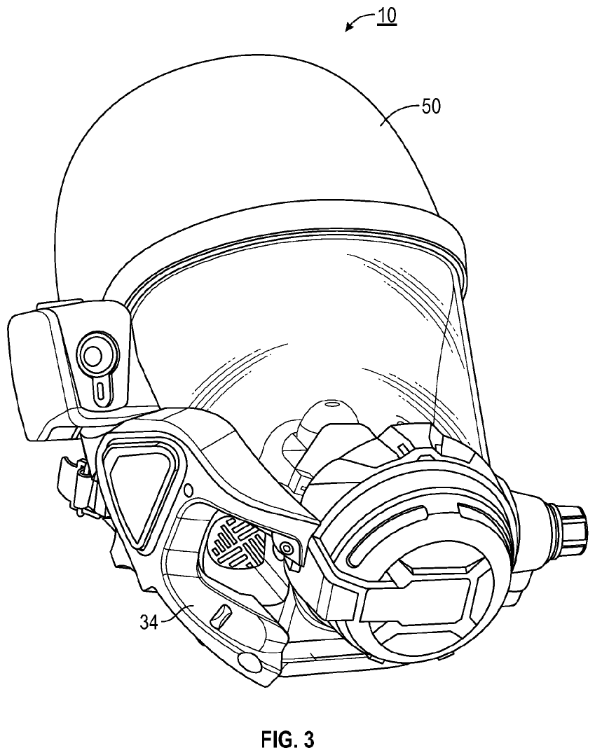

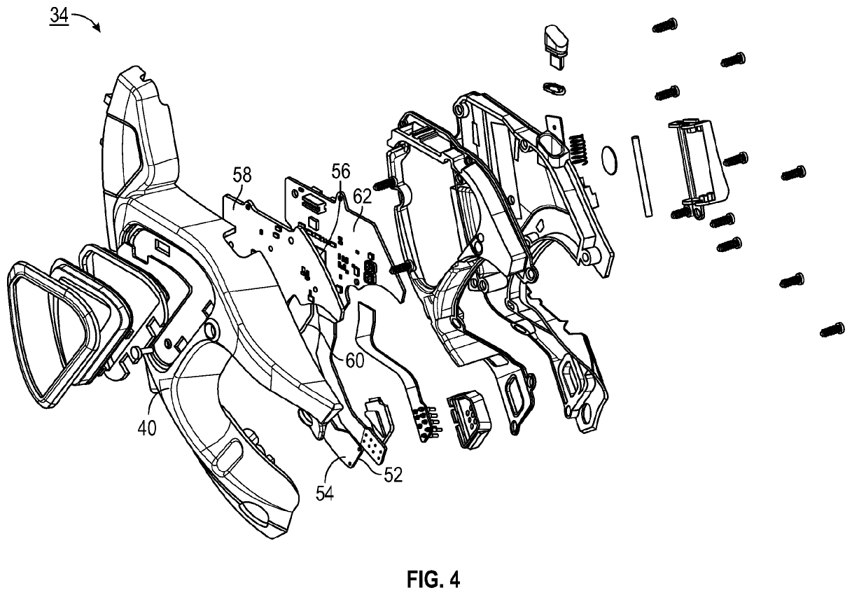

FIG. 3 shows an example of audio communication module 34 assembled and attached to the RPM 10. FIG. 4 shows an exploded view of an embodiment of the audio communication module 34. The audio communication module 34 of FIG. 4 includes a first antenna 52 on a first PCB 54 and a second antenna 56 located on an edge of a second PCB 58. The first PCB 54 is electrically connected to the second PCB 58 by a transmission line 60, which preferably is flexible, such as a coaxial cable. The transmission line 60 may be, for example, a coaxial cable, an optical fiber or a rigid transmission line such as a stripline.

A third PCB 62 may also be provided. The first PCB 54, second PCB 58 and third PCB 62 are shaped and positioned to be enclosed by the housing 40.

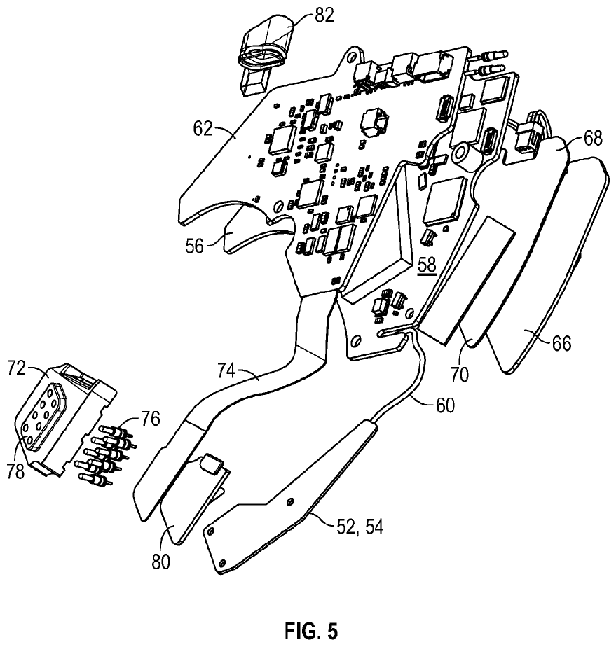

An opposite view of the PCBs 54, 58 and 62, is shown in FIG. 5. In addition, FIG. 5 shows a near field communication (NFC) antenna 66. In some embodiments, the NFC antenna is used to facilitate pairing of mask to mask communications, such as may be used by a group of first responders at a premises. The NFC antenna 66 may be shielded from the PCB 58 by a ferrite shielding 68. The ferrite shielding 68 may adhere to the PCB 58 by magnetic shielding tape 70 to substantially reduce remote speaker microphone (RSM) interference.

Between the third PCB 62 and the ferrite shielding 68 is the second PCB 58 which includes the second antenna 56. The second antenna 56 may be formed by plating at least a portion of an edge of the second PCB 58 with metal to make the plated edge portion electrically conductive, and therefore radiative when excited by a time-varying current. The third PCB 62 is electrically connected to the UEP block 72 via a UEP flexible cable 74, which may be connected to conducting pins 76. The conducting pins 76 are connected to a UEP interface 78 of the UEP block 72 to form the UEP connector 46. A potting cap 80 separates the UEP flexible cable 74 from the first antenna 52. Note that a light pipe 82 may be incorporated into the audio communication module 34 to enable electronics on the third PCB 62 to sense light and react in response to changes in light intensity.

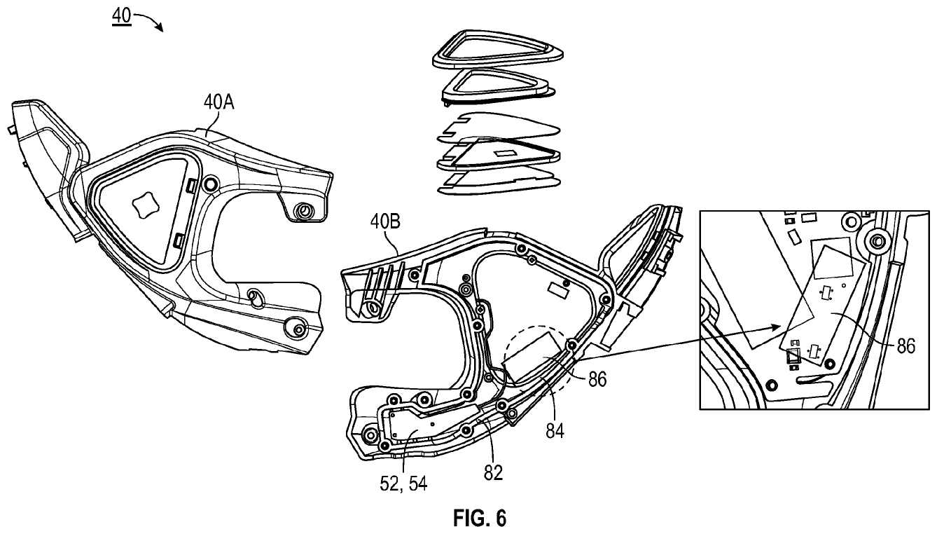

FIG. 6 shows a view of the outer housing 40 in two parts, namely parts 40-A and 40-B. Either or both of outer housing parts 40-A and 40-B may include at least one wall 82 that encompasses at least a portion of an edge of the first PCB 54. A wall 84, which may be separate from the at least one wall 82 that encompasses the edge of the first PCB 54, may surround at least a portion of a magnetic field strip 86. The magnetic field strip 86 may be positioned so as to shield hall sensors on another surface from RSM interference. Note that the magnetic field strip 86 may be the same as the magnetic shielding tape 70.

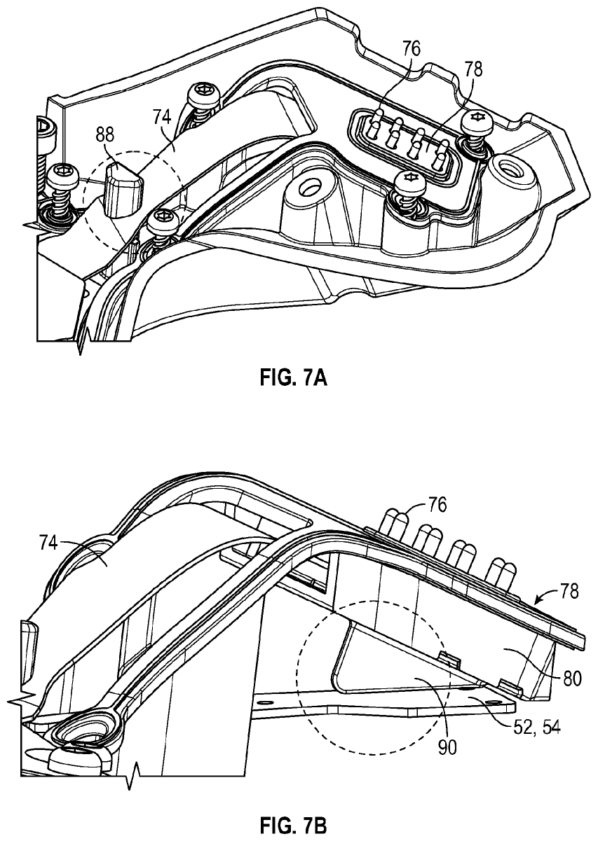

FIG. 7A is a perspective view of the UEP interface 78 integrally or removably embedded between outer housing parts 40-A or 40-B. A rib or spacer 88 is positioned to support and position the UEP flexible cable 74 away from the first PCB 54.

FIG. 7B is a different perspective view of the UEP block 78 (with UEP interface 78) integrally or removably embedded between outer housing parts 40-A and 40-B. The potting cap 80 has a rib 90 added to or integrally formed with the potting cap 80. A purpose of the rib 90 is to secure, hold and/or keep the first antenna 52 and the first PCB 54 in a fixed position.

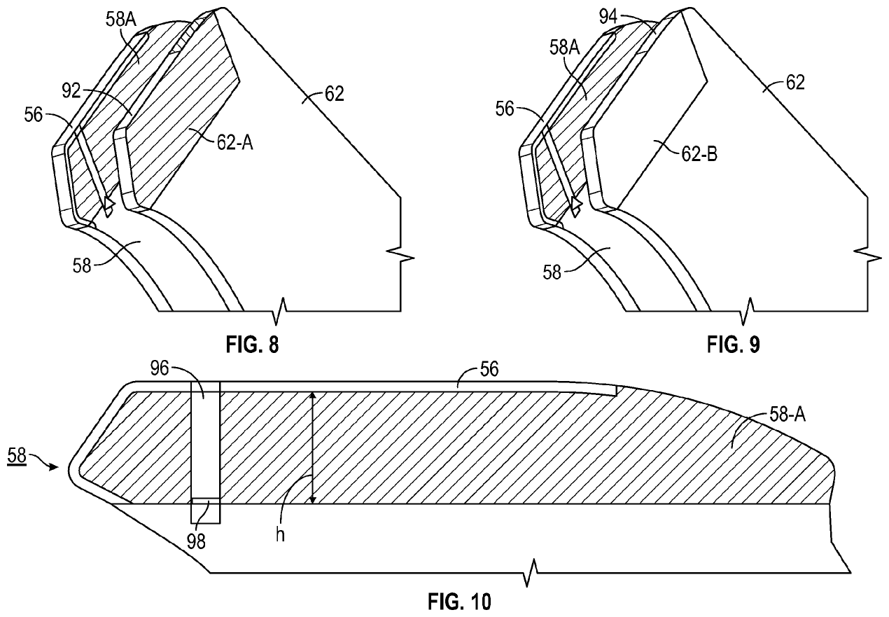

FIG. 8 shows the second PCB 58 and the third PCB 62. In the example of FIG. 8, the second antenna 56 includes metal on the edge of the second PCB 58. Also, the second PCB 58 has an area 58-A in which metal is absent. The non-metallized area 58-A is adjacent to the metal plated edge of the second PCB 58. An example height, h, as shown in FIG. 10, of the non-metallized area 58-A is 6.2 millimeters for operation around 1.9 GHZ. In the example of FIG. 8, a portion of the edge 92 of the third PCB 62 is metal. The area 62-A of the third PCB 62 is not metal. FIG. 9 is an example that is similar to FIG. 8, except that the area 62-B of the third PCB 62 is metallized in FIG. 9 and the edge 94 is metallized.

FIG. 10 is a side view of the second antenna 56 located on an edge of the second PCB 58. The second PCB 58 has the area 58-A that is not metallized, in this example. The second antenna 56 may be fed by a conducting strip 96 having a 50-ohm feed point 98.

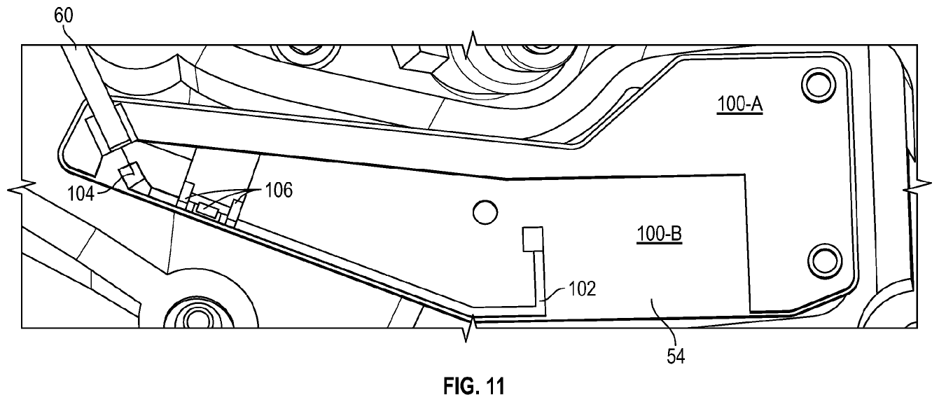

FIG. 11 is a view of the first PCB 54 with a metallized surface area 100-A, a non-metallized surface area 100-B, and a metal strip line 102. The metallized surface area 100 A and metal strip line 102, taken collectively, may be considered to be the first antenna 52. Persons having ordinary skill in the art will recognize that the strip line 102 could be considered as a feed structure or impedance matching structure that is separate from the first antenna 52.

For example, the transmission line 60 may be a coaxial cable, having a first end which may be connected to the first antenna 52 by connecting the center conductor of the cable to the strip line 102 at a junction 104 at or near an end of the strip line 102. The end of the cable opposite the first end is connected to the second PCB 58. Thus, the cable carries the signal received by the first antenna 52 to the second PCB 58 where it is processed in combination with the signal received by the second antenna 56. Reciprocally, a signal radiated by the first antenna 52 may be in a relative phase relationship with the signal radiated by the second antenna 56.

Spacing the first antenna 52 and the second antenna 56 sufficiently apart yields antenna spatial diversity. Antenna spatial diversity overcomes multipath fading when the two antennas are sufficiently spaced apart so that the paths for each antenna are sufficiently uncorrelated, and are therefore unlikely to fade at the same time. In FIG. 11, pads 106 are soldering pads. Pads 106 allow soldering of the transmission line 60 to the pads to form an electrical connection between the transmission line 60 and the stripline 102.

Note that the length and path of the strip line 102 may be adjusted to tune the first antenna 52. The strip line 102 and/or junction 104 may be configured to exhibit a 50-ohm impedance to match the impedance of the cable to minimize reflection losses in some embodiments.

In some embodiments, the radiation efficiency of the first antenna 52 and the second antenna 56 are similar within a frequency range.

According to one aspect, a communication module 34 for a respiratory protection mask 10, is provided. The communication module is configured to send and receive radio signals, and includes a housing 40 having at least partially enclosed therein a first antenna 52 and a second antenna 56 separated from the first antenna 52 to achieve antenna spatial diversity.

According to this aspect, in some embodiments, a shape of the housing 40 that encloses the first and second antennas conforms to a shape of the respiratory protection mask 10. In some embodiments, the housing 40 is removably attachable to the respiratory protection mask 10 such that when attached, the first antenna 52 is positioned at a first location with respect to the mask 10 and 56 separated the second antenna 56 is positioned at a second location separate from the first location. In some embodiments, the first location is a front region of the mask 10 and the second location is a side region of the mask 10. In some embodiments, the first antenna 52 is on a first printed circuit board 54 and the second antenna 56 is on a second printed circuit board 56 electrically connected to the first circuit board by a transmission line, the first and second printed circuit boards being separated within the housing 40 to achieve the separation between the first and second antennas. In some embodiments, the second antenna 56 includes a plated edge portion of the second printed circuit board 56. In some embodiments, the first printed circuit board 54 has printed thereon the first antenna 52 and a strip line feed structure 102. In some embodiments, further comprising a connector interface 76 and a flexible ribbon cable 74 connecting the second printed circuit board 56 to the connector interface 76. In some embodiments, the flexible ribbon cable 74 is spaced apart from the first printed circuit board 54 by a spacer. In some embodiments, the connector interface 76 includes a potting cap 80 and a rib 90 to space the potting cap 80 apart from the first printed circuit board 54. In some embodiments, the communication module 34 further includes a magnetic shield strip 86 and at least one hall sensor, the magnetic shield strip 86 positioned to shield the hall sensors from remote speaker microphone (RSM) interference.

According to another aspect, a respiratory protection mask 10 includes a facepiece to cover a face of a wearer of the respiratory protection mask 10. The respiratory protection mask 10 also includes an audio communication module 34 removably attachable to a side of the respiratory protection mask 10, the audio communication module 34 having a housing 40 configured to at least partially enclose two spatially separated antennas 52, 56 to achieve antenna spatial diversity.

According to this aspect, in some embodiments, the two spatially separated antennas 52, 56 are on two spatially separated printed circuit boards 54, 58 electrically connected by a transmission line 60, the two spatially separated printed circuit boards 54, 58 being at least partially enclosed within the housing 40, the housing 40 shaped to have a non-planar curvature that conforms to a non-planar curvature of the respiratory protection mask 10. In some embodiments, one of the two spatially separated antennas 52, 56 includes a metal-plated edge portion of a printed circuit board 54, 58. In some embodiments, the respiratory protection mask 10 further includes a flexible ribbon cable 74 configured to connect one of the two spatially separated printed circuit boards 54, 58 to an audio communication module input/output port. In some embodiments, the audio communication module 34 is further configured with a connector 76 and a rib 90 configured to contact and offset one of the two spatially separated printed circuit boards 54, 58. In some embodiments, the flexible ribbon cable 74 is spaced apart from the other of the two spatially separated printed circuit boards 54, 58. In some embodiments, the flexible ribbon cable 74 is spaced apart from the other of the two spatially separated printed circuit boards 54, 58 by a spacer 88 that extends from a housing 40 of the audio communication module 34. In some embodiments, the two spatially separated antennas 52, 56 are on a single printed circuit board. In some embodiments, one of the two spatially separated antennas 52, 56 includes a metal plated edge portion. In some embodiments, at least one of the two spatially separated antennas includes a strip line feed structure 102.

It will be appreciated by persons skilled in the art that the present embodiments are not limited to what has been particularly shown and described herein above. In addition, unless mention was made above to the contrary, it should be noted that all of the accompanying drawings are not to scale. A variety of modifications and variations are possible in light of the above teachings.

1. A communication module for a respiratory protection mask, the communication module configured to send and receive radio signals, the communication module comprising:
a housing having at least partially enclosed therein:
a first antenna; and
a second antenna separated from the first antenna to achieve antenna spatial diversity.

2. The communication module of claim 1, wherein a shape of the housing that encloses the first and second antennas conforms to a shape of the respiratory protection mask.

3. The communication module of claim 2, wherein the housing is removably attachable to the respiratory protection mask such that when attached, the first antenna is positioned at a first location with respect to the mask and antenna separated the second antenna is positioned at a second location separate from the first location.

4. The communication module of claim 3, wherein the first location is a front region of the mask and the second location is a side region of the mask.

5. The communication module of claim 2, wherein the first antenna is on a first printed circuit board and the second antenna is on a second printed circuit board electrically connected to the first circuit board by a transmission line, the first and second printed circuit boards being separated within the housing to achieve the separation between the first and second antennas.

6. The communication module of claim 5, wherein the second antenna includes a plated edge portion of the second printed circuit board.

7. The communication module of claim 5, wherein the first printed circuit board has printed thereon the first antenna and a strip line feed structure.

8. The communication module of claim 5, further comprising a connector interface and a flexible ribbon cable connecting the second printed circuit board to the connector interface.

9. The communication module of claim 8, wherein the flexible ribbon cable is spaced apart from the first printed circuit board by a spacer.

10. The communication module of claim 9, wherein the connector interface includes a potting cap and a rib to space the potting cap apart from the first printed circuit board.

11. The communication module of claim 10, further comprising a magnetic shield strip and at least one hall sensor, the magnetic shield strip positioned to shield the hall sensors from remote speaker microphone (RSM) interference.

12. A respiratory protection mask, comprising:
a facepiece to cover a face of a wearer of the respiratory protection mask;
an audio communication module removably attachable to a side of the respiratory protection mask, the audio communication module having a housing configured to at least partially enclose two spatially separated antennas to achieve antenna spatial diversity.

13. The respiratory protection mask of claim 12, wherein the two spatially separated antennas are on two spatially separated printed circuit boards electrically connected by a transmission line, the two spatially separated printed circuit boards being at least partially enclosed within the housing, the housing shaped to have a non-planar curvature that conforms to a non-planar curvature of the respiratory protection mask.

14. The respiratory protection mask of claim 13, wherein one of the two spatially separated antennas includes a metal-plated edge portion of a printed circuit board.

15. The respiratory protection mask of claim 14, further comprising a flexible ribbon cable configured to connect one of the two spatially separated printed circuit boards to an audio communication module input/output port.

16. The respiratory protection mask of claim 15, wherein the audio communication module is further configured with a connector and a rib configured to contact and offset one of the two spatially separated printed circuit boards.

17. The respiratory protection mask of claim 15, wherein the flexible ribbon cable is spaced apart from the other of the two spatially separated printed circuit boards.

18. The respiratory protection mask of claim 15, wherein the flexible ribbon cable is spaced apart from the other of the two spatially separated printed circuit boards by a spacer that extends from a housing of the audio communication module.

19. The respiratory protection mask of claim 12, wherein the two spatially separated antennas are on a single printed circuit board.

20. (canceled)

21. The respiratory protection mask of any of claim 12, wherein at least one of the two spatially separated antennas includes a strip line feed structure.
